(19) United States
(12) Patent Application Publication
(10) Pub. No.: US 2025/0048745 A1
(43) Pub. Date: Feb. 6, 2025

(54) INTEGRATED CIRCUIT WITH I/O PAD CLUSTERS AND ESD ROUTING

(71) Applicant: STMicroelectronics International N.V., Geneva (CH)

(72) Inventors: Sebastien DEDIEU, La Terrasse (FR); Frederic BAILLEUL, Brignoud (FR)

(73) Assignee: STMicroelectronics International N.V., Geneva (CH)

(21) Appl. No.: 18/365,890

(22) Filed: Aug. 4, 2023

(51) Int. Cl. H01L 27/02

(52) U.S. Cl. CPC H01L 27/0292

(57) ABSTRACT

An integrated circuit package includes an integrated circuit die. The integrated circuit die includes core circuitry implemented in one or more layers of semiconductor material, a first cluster of first contact pads formed of a top metal layer of the integrated circuit die and coupled to the core circuitry, a second cluster of second contact pads formed of the top metal layer and coupled to the core circuitry, a first ESD protection line formed of the top metal layer extending between an area of the first cluster and an area of the second cluster, and ESD protection circuitry in the one or more layers of semiconductor material coupling each of the first contact pads and each of the second contact pads to the first ESD protection line by ESD protection circuitry. The integrated circuit package includes a passivation layer on the integrated circuit die and a second ESD protection line on the passivation layer formed of a redistribution metal layer and shorting a portion of the first ESD protection line.

### BACKGROUND

### Technical Field

The present disclosure generally relates to integrated circuits, and more particularly to ESD protection in integrated circuits.

### Description of the Related Art

Integrated circuits often include various circuit structures including transistors, metal tracks, conductive vias, contact pads and other structures. In many cases, integrated circuits include large numbers of transistors in complex arrangements. In order to enable larger numbers of transistors within the integrated circuit, the sizes of the transistors continue decrease. This results in transistors having very small features.

Because the transistors may have very small features, the transistors may also have very low voltage ratings. A voltage rating corresponds to the maximum voltage difference that can be present across any two terminals of the transistor without damaging the transistor. The smallest transistors in the core circuitry may have a voltage ratings less than 2 V.

In some cases, it is possible that high voltages may appear across two or more contact pads or terminals of an integrated circuit. In some cases, an electrostatic charge can build up at a pad or terminal, resulting in an electrostatic discharge or other type of overvoltage event at the pad or terminal. In an electrostatic discharge event, high currents may flow through contact pads of the integrated circuit. If the sensitive transistors receive high currents or are otherwise subjected to high voltages from a contact pad or terminal, it is possible that the transistors will be damaged.

Integrated circuit packages are generally processed in two phases: the wafer processing stage and the packaging stage. The integrated circuits are formed in a wafer during the wafer processing stage. The wafer processing stage can include formation of the transistors, the dielectric layers, metal interconnections structures, and other structures within an integrated circuit die. During the packaging stage, the integrated circuit dies are diced from a wafer and packaged. This can include forming passivation layers and metal redistribution layers and attaching solder balls, solder bumps, or other types of connectors. During the wafer processing stage, there is less risk of very high voltages appearing across terminals of an integrated circuit die. During the packaging stage, there is a higher risk that very high voltages may appear across terminals of the integrated circuit die. Accordingly, there may be lower ESD protection standards for the wafer processing stage than for the packaging stage.

Various ESD protection structures may be implemented to protect integrated circuits at various stages of processing. However, the manner in which these ESD protection structures are implemented may negatively impact the number and density of transistors that can be formed in the integrated circuit die.

### BRIEF SUMMARY

Embodiments of the present disclosure provide an integrated circuit that is able to provide effective ESD protection for both the wafer processing stage and the packaging stage with little area consumption. In particular, an integrated circuit in accordance with principles of the present disclosure includes clusters of contact pads at the top surface of the integrated circuit die. A first ESD protection line is formed at the top surface of the die extending between the clusters of contact pads. The first ESD protection line is formed of a metal layer of the integrated circuit die having a relatively low resistivity that satisfies wafer processing ESD protection standards. A second ESD protection line is formed on the integrated circuit die during the packaging stage from a metal redistribution layer that has a lower resistivity the than the first ESD protection line. The second ESD protection line is shorted with the first ESD protection line and satisfies the higher packaging stage ESD protection standards.

The combination of the high-level and package level ESD protection lines also enables the use of clusters of contact pads further away from the edges of the die than typically occurs in traditional packages. The result is that peripheral portions of the die can be utilized to increase circuit density in the semiconductor layer rather than devoting the entire peripheral portion of the die to ESD ground rings.

In one embodiment, an integrated circuit package includes an integrated circuit die including core circuitry implemented in one or more layers of semiconductor material and a first cluster of first contact pads formed of a top metal layer of the integrated circuit die and coupled to the core circuitry. In one embodiment, the integrated circuit die includes a second cluster of second contact pads formed of the top metal layer and coupled to the core circuitry, a first ESD protection line formed of the top metal layer extending between an area of the first cluster and an area of the second cluster, and ESD protection circuitry in the one or more layers of semiconductor material coupling each of the first contact pads and each of the second contact pads to the first ESD protection line by ESD protection circuitry. The integrated circuit package includes a passivation layer on the integrated circuit die and a second ESD protection line on the passivation layer formed of a redistribution metal layer and shorting a portion of the first ESD protection line.

In one embodiment, a method includes forming a plurality of metal layers of an integrated circuit die above a semiconductor substrate of the integrated circuit die, the plurality of layers including a top metal layer and forming, from the top metal layer, a first cluster of first contact pads, a second cluster of second contact pads, and a first ESD protection line coupled to each of the first and second contact pads via ESD protection circuitry. The method includes forming a passivation layer on the first ESD protection line and forming, from a redistribution metal layer on the passivation layer, a second ESD protection line electrically coupled to the first ESD protection line via a first opening in the passivation layer adjacent to the first cluster and via a second opening in the passivation layer adjacent to the second cluster.

In one embodiment, a method includes a forming, from a top metal layer of an integrated circuit die a first cluster of first interior contact pads adjacent to each other, a second cluster of second interior contact pads adjacent to each other, a plurality of peripheral contact pads adjacent to an edge of the integrated circuit die, and a first ESD protection line extending between the first cluster and the second cluster and electrically coupled to each of the first and second interior contact pads by ESD protection circuitry. The method includes forming, from a redistribution metal layer over the top metal layer, a second ESD protection line shorting out at least a portion of the first ESD protection line and forming a plurality of solder connection structures each coupled to a respective first interior contact pad, a second interior contact pad, or a peripheral contact pad by portions of the redistribution metal layer.

### BRIEF DESCRIPTION OF THE SEVERAL VIEWS OF THE DRAWINGS

FIG. 1 is a block diagram of an integrated circuit package, in accordance with one embodiment.

FIG. 2 is a simplified top view of an integrated circuit package, in accordance with one embodiment.

FIGS. 3A-3C are cross-sectional views of an integrated circuit package at various stages of processing, in accordance with one embodiment.

FIG. 4 is a cross-sectional view of a portion of an integrated circuit package, in accordance with one embodiment.

FIG. 5 is a cross-sectional view of a portion of an integrated circuit package, in accordance with one embodiment.

FIG. 6 is a flow diagram of a method for forming an integrated circuit package, in accordance with one embodiment.

FIG. 7 is a flow diagram of a method for forming an integrated circuit package, in accordance with one embodiment.

### DETAILED DESCRIPTION

In the following description, certain specific details are set forth in order to provide a thorough understanding of various disclosed embodiments. However, one skilled in the relevant art will recognize that embodiments may be practiced without one or more of these specific details, or with other methods, components, materials, etc. In other instances, well-known systems, components, and circuitry associated with integrated circuits have not been shown or described in detail, to avoid unnecessarily obscuring descriptions of the embodiments.

Unless the context requires otherwise, throughout the specification and claims which follow, the word “comprise” and variations thereof, such as, “comprises” and “comprising” are to be construed in an open, inclusive sense, that is as “including, but not limited to.” Further, the terms “first,” “second,” and similar indicators of sequence are to be construed as interchangeable unless the context clearly dictates otherwise.

Reference throughout this specification to “one embodiment” or “an embodiment” means that a particular feature, structure or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its broadest sense, that is as meaning “and/or” unless the content clearly dictates otherwise.

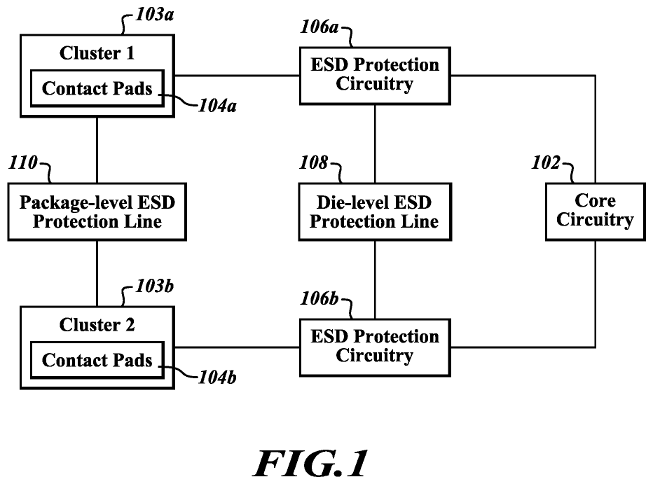

FIG. 1 is a block diagram of an integrated circuit package 100, in accordance with one embodiment. The integrated circuit package includes an integrated circuit die (not labeled) including core circuitry 102, clusters 103a and 103b of contact pads 104a and 104, respectively, ESD protection circuitry 106a, 106b, and a die-level ESD protection line 108. The integrated circuit package 100 also includes a package level ESD protection line 110 that will be connected through the clusters 103 of contact pads 104. As will be set forth in more detail below, the combination of components of the integrated circuit package 100 provide effective ESD protection while enabling improved usage of integrated circuit area.

Some reference numbers used herein may include suffixes “a”, “b”, “c”, “d”, or “e”. The suffixes may be utilized when referring to a specific component. However, when a specific component is not referenced, the suffixes may not be utilized. For example, when referring to specifically the cluster 103a the suffix “a” may be utilized. However, when referring to clusters in general, the clusters may be collectively referred to as clusters 103 without the suffix.

The core circuitry 102 can include a large number of transistors coupled together in complex arrangements. The transistors of the core circuitry 102 may be implemented in accordance with one or more semiconductor layers within the integrated circuit die. The core transistors can correspond to CMOS transistors including planer transistors, FinFET transistors, or other types of transistors.

The integrated circuit die may include, above the one or more semiconductor layers, a series of dielectric layers. A plurality of metal layers may be embedded within the series of dielectric layers. The metal layers can include complex interconnection schemes including conductive vias and metal lines coupling the transistors of the core circuitry 102 in complex arrangements. The transistors cooperate to process data, to write data to memory, to read data from memory, and to execute software instructions.

Because there may be a large number of transistors performing a large number of tasks, it is possible that the transistors of the core circuitry 102 can utilize a large amount of power. The high-power usage can result in the generation of large amounts of heat. This can be problematic if the integrated circuit 100 is not able to safely dissipate the heat generated by the core circuitry 102.

In order to reduce the overall area, transistor sizes may be reduced. Voltages are reduced accordingly. The transistors of the core circuitry 102 may include relatively thin gate dielectrics. For example, the gate dielectrics of the transistors in the core circuitry 102 may include thicknesses between 10 Å and 200 Å. In one embodiment, there may be transistors of multiple sizes including gate dielectrics of differing thickness. For example, in one embodiment there are transistors with gate dielectrics of 17 Å in thickness, transistors with gate dielectrics of 50 Å in thickness, and transistors with gate dielectrics of 150 Å in thickness. Other thicknesses for the gate dielectrics of the transistors in the core circuitry 102 can be utilized without departing from the scope of the present disclosure. As will be described in more detail below, because the transistors of the core circuitry 102 have relatively thin gate dielectrics, the transistors of the core circuitry 102 may be more susceptible to damage from overvoltage and ESD events.

The core circuitry 102 receives signals or data from sources external to the integrated circuit package 100 via the contact pads 104. The core circuitry 102 may also pass signals or data to sources external to the integrated circuit package 100 via the contact pads 104. Accordingly, the contact pads 104 may be called I/O pads. Some of the contact pads 104 may be data I/O pads. Some of the contact pads 104 may receive a supply voltage or ground. Some of the contact pads may be utilized for configuration of the integrated circuit. There may be a large number of contact pads 104 that perform various functions. In any case, at least some of the contact pads 104 are connected to the core circuitry 102.

The contact pads 104 correspond to metal structures formed from a highest metal layer of the integrated circuit die. In conventional terminology, a first metal layer (closest to the core circuitry 102) may be referred to as metal 1 (M1), a next metal layer may be referred to as metal to (M2), etc. The contact pads 104 are formed from a highest metal layer of the integrated circuit die. If there are five metal layers, then the contact pads 104 are formed in metal five (M5). Each metal layer can include one or more of aluminum, tungsten, cobalt, titanium, or other suitable conductive materials.

As described previously, the integrated circuit die may include a plurality of dielectric layers. The dielectric layers can include silicon oxide, silicon nitride, SiCN, SiCON, or other suitable dielectric layers. In conventional terminology, the components of the integrated circuit dies such as the core circuitry 102 and the various metal lines may be described as being “formed in silicon”. This is because in many cases the semiconductor layers include silicon (such as monocrystalline silicon, monocrystalline silicon germanium, or other silicon-based semiconductors) and the dielectric layers also include silicon (such as silicon dioxide, silicon nitride etc.). Nevertheless, the semiconductor layers can include semiconductor materials other than silicon. Furthermore, dielectric layers that do not include silicon can also be utilized.

The core circuitry 102 and the various metal layers (e.g., M1-M5) are formed during the wafer processing stage. In particular, the integrated circuit die is initially part of a semiconductor wafer in which a large number of identical integrated circuit dies are formed during the wafer processing stage. After formation and patterning of the final metal layer to produce contact pads 104 and other structures, an initial passivation layer may be formed at the wafer processing stage. This may correspond to completion of the wafer processing stage.

After the wafer processing stage is complete, a packaging stage is performed. During the packaging stage, a redistribution metal layer is formed in electrical contact with the contact pads 104. The redistribution metal layer may be patterned to form metal traces electrically connecting the contact pads 104 to areas at which electrical connectors such as solder balls, solder bumps, or other types of electrical connectors are formed. During the wafer processing stage additional passivation layers are formed and patterned to expose portions of the redistribution metal layer at which electrical connectors will be placed. Additional conductive layers may also be utilized to enhance electric coupling.

During the wafer processing stage, there is little or no opportunity that humans may handle a wafer and accidentally short circuit the exposed contact pads 104 and inadvertently cause a high-voltage ESD event. This is because wafer processing is almost entirely automated in highly controlled environments. Accordingly, ESD protection standards at the wafer processing stage may call for protection for up to 700 V. In contrast, at the packaging stage it is possible that a human may short to contact pads by handling or touching solder balls or other electrical connectors can cause a very high-voltage ESD event. ESD protection standards for the wafer processing stage may call for protection for 2000 V or more.

The integrated circuit package 100 includes a die-level ESD protection line 108. The die-level ESD protection line corresponds to a conductive line formed of the same metal layer as the contact pads 104 extending between clusters 103 of contact pads 104. For example, the ESD protection line may extend from an area adjacent to the contact pads 104a of the cluster 103a to an area adjacent to the contact pads 104b of the cluster 103b. The die-level ESD protection line 108 helps ensure that in the event of an ESD event there is a low resistance path between the contact pads 104a/b of the clusters 103a/b. The ESD protection line 108 may be coupled to an ESD ground path or ground line. This helps ensure that if an ESD event occurs, high currents may flow through the ESD protection line 108 to ground rather than through the core circuitry 102. This can help ensure that the transistors of the core circuitry 102 are not damaged in an ESD event.

The integrated circuit package 100 also includes ESD protection circuitry 106. This can include circuitry that helps ensure that currents can flow through the ESD protection line 108 rather than through the core circuitry 102. The ESD protection circuitry 106a is coupled between the contact pads 104a of the cluster 103a and the die-level ESD protection line 108. The ESD protection circuitry 106b is coupled between the contact pads 104b of the cluster 103b and the die-level ESD protection line 108.

The ESD protection circuitry 106 can include diodes that are configured to pass currents between the contact pads 104 and the die-level ESD protection line 108 during high-voltage ESD events but that prevent shorting of the contact pads 104 with each other and with ground during normal operation in which an ESD event is not present. More particularly, the ESD protection circuitry 106a ensures that high currents can be passed from the contact pads 104a to the die-level protection line 108 during a high-voltage ESD event while preventing shorting of the contact pads 104a with each other or with the die-level ESD protection line 108 during standard operation. Similarly, the ESD protection circuitry 106b ensures that high currents can be passed from the contact pads 104b to the die-level protection line 108 during a high-voltage ESD event while preventing shorting of the contact pads 104b with each other or with the die-level ESD protection line 108 during standard operation.

As described previously, the ESD protection line 108 has a resistivity that is sufficiently low to satisfy ESD protection standards at the wafer processing stage. In one embodiment, the die-level ESD protection line 108 is made of aluminum and has a total resistance of about 8 ohms. Other materials and resistances can be utilized for the die-level ESD protection line 108 without departing from the scope of the present disclosure.

During the wafer processing stage, a package level ESD protection line 110 is formed. In particular, the package level ESD protection line 110 is formed from the previously described redistribution metal layer. The package level ESD protection line 110 shorts out the die-level ESD protection line 108. For example, prior to formation of the redistribution metal layer, a passivation layer may be patterned to expose the contact pads 104 and multiple portions of the die-level ESD protection line 108. Accordingly, when the redistribution metal layer is formed and patterned, the package level ESD protection line 110 remains in contact with the die-level ESD protection line 108 and multiple locations.

In one embodiment, the redistribution metal layer is more highly conductive than the material of the die-level ESD protection line 108. This can help ensure that the resistance of the package level ESD protection line 110 is sufficiently low to satisfy the higher ESD protection standards of the packaging stage. In one example, the material of the redistribution metal layer and, thus, the package level ESD protection layer 110, is copper. However, other materials may be utilized without departing from the scope of the present disclosure. The total resistance of the package level ESD protection line 110 may be less than 1 ohm. The result is that the package level ESD protection line 110 satisfies the package stage ESD protection standards.

One benefit of utilizing the combination of the die-level ESD protection line 108 and the package level ESD protection line 110 is that contact pads 104 can be formed in clusters 103 away from the edges of the integrated circuit die. In some conventional configurations, all contact pads are formed around the periphery of the integrated circuit die. An ESD protection range may be formed around the entire periphery of the die below the surface. This may inhibit the ability to utilize area of the semiconductor layers that are near the edge of the die. This can result in lower densities or numbers of transistors formed in the core circuitry 102.

However, because the overlapping die-level ESD protection line 108 and the package level ESD protection lines 110 can be formed as described above, the contact pads 104 can be formed in clusters 103 connected together by the die-level ESD protection line 108 in order to provide ESD routing to protect the core circuitry 102. This not only provides good ESD protection, but peripheral areas of the die can be utilized for the transistor formation.

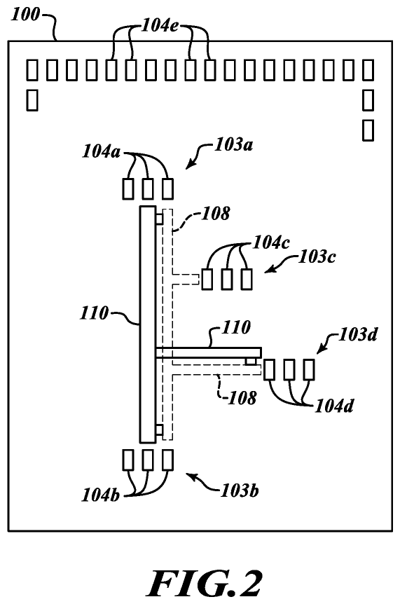

FIG. 2 is a simplified top view of an integrated circuit package 100, in accordance with some embodiments. The top view of the integrated circuit package 100 illustrates a plurality of contact pads 104a-d formed in the interior clusters 103a-d. The top view of the integrated circuit package 100 also illustrates peripheral contact pads 104e arrange their portion of the edge of the integrated circuit package 100. Large portions of the peripheral area of the integrated circuit die did not have contact pads 104.

The top view of the integrated circuit package illustrates, in dashed lines, the die-level ESD protection lines 108 extending between clusters 103a-d. In practice, the die-level ESD protection line 108 is formed of a same metal layer as the contact pads 104. However, the die-level ESD protection line 108 is shown in dashed lines because an initial passivation layer would cover the die-level ESD protection line 108 while leaving the contact pads 104 are exposed.

For simplicity, the top view of the integrated circuit illustrates the package level ESD protection line 110 formed of the redistribution metal layer without showing other portions of the redistribution metal layer. In practice, the redistribution metal layer may be patterned to form traces that connect to each of the contact pads 104 so that connectors such as solder bumps or solder balls can be placed to electrically connect to the contact pads 104.

Though not apparent, the package level ESD protection line 110 directly contacts the die-level ESD protection line at various locations 113. The locations 113 may correspond to openings in one or more passivation layers exposing portions of the die-level ESD protection line 108. In practice, the package level ESD protection line 110 may directly overlie the die-level ESD protection line 108. Various other configurations of clusters 103 contact pads 104, die-level ESD protection line 108, and package level ESD protection line 110 can be utilized without departing from the scope of the present disclosure.

The clusters 103 of contact pads 104 enable avoiding long connections from attached solder balls (not shown) and the ESD protection circuitry. The result is that there is shorter connection and lower resistivity between the pack ball and the ESD protection. Another result is that there is shorter connection and lower resistivity between the solder ball and the high current circuitry. There is a corresponding lower voltage drop.

Furthermore, the clusters 103 of contact pads 104 enable avoiding long redistribution layer connections to the edge of the die. This provides the possibility to increase the surface area of the redistribution metal layer for better thermal dissipation. In other words, there is more area over which redistribution metal layer can be deposited for better thermal dissipation.

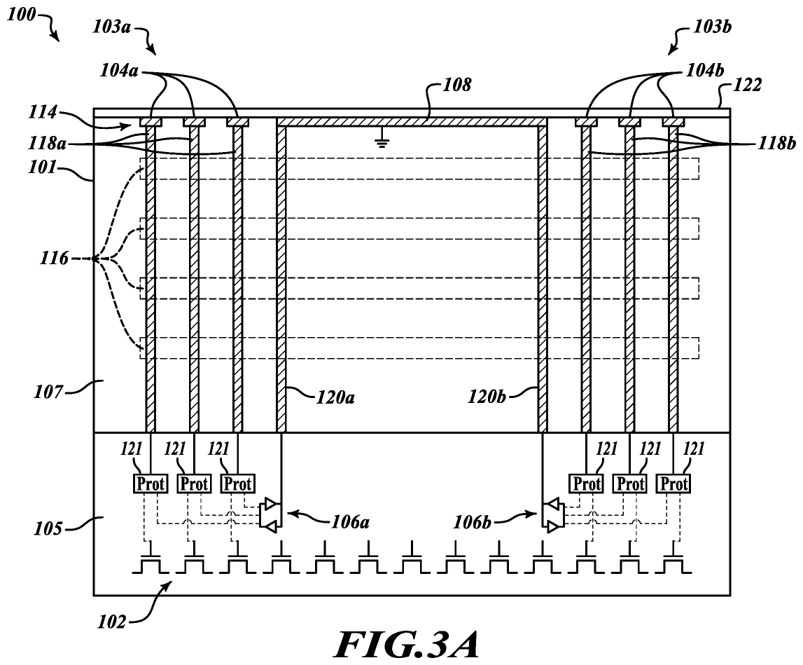

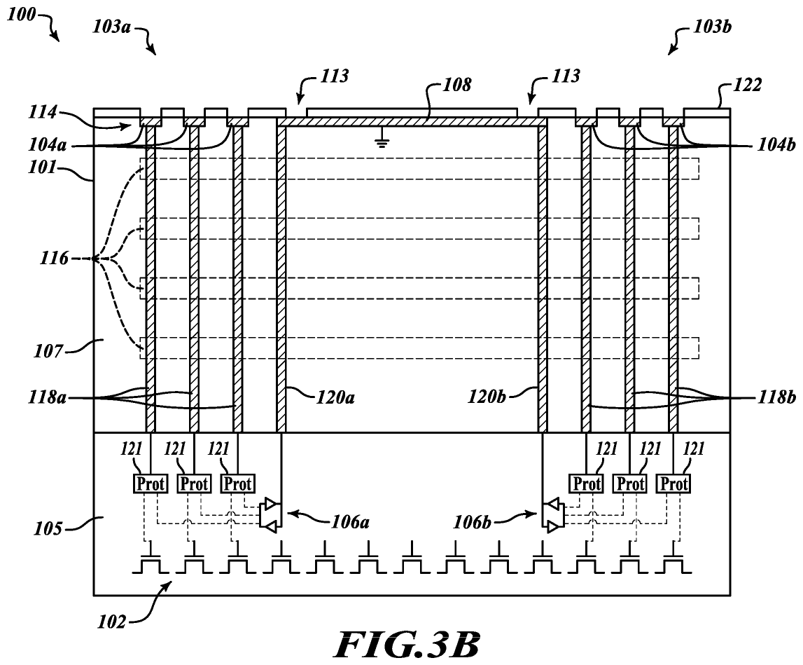

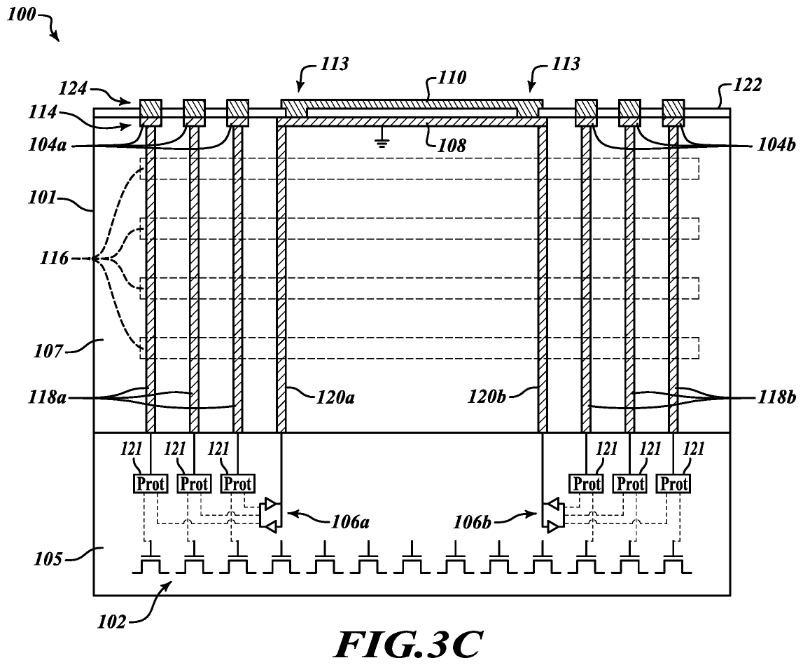

FIG. 3A is a cross-sectional view of an integrated circuit package 100, at or near the end of the wafer processing stage, according to one embodiment. The integrated circuit package 100 includes an integrated circuit die 101. The integrated circuit die 101 includes one or more semiconductor layers 105. Core circuitry 102 including a plurality of transistors has been formed in conjunction with the one or more semiconductor layers 105. ESD protection circuitry 106a and 106b has been formed in conjunction with the one or more semiconductor layers 105.

The integrated circuit die 101 includes a dielectric stack 107 including a plurality of dielectric layers formed above the one or more semiconductor layers 105. As described previously, the dielectric layers of the dielectric stack can include a large number of dielectric layers including layers of silicon oxide, layers of silicon nitride, layers of SiCN, layers of SiCON, or other suitable dielectric layers.

The integrated circuit die 101 includes four metal layers 116 corresponding to metal layers M1-M4 formed in the dielectric stack 107. Though not shown, the metal layers 116 are patterned to form metal tracks. Though not shown, conductive vias are formed between the metal layers in order to provide connections at selected locations between the metal tracks of the metal layers.

The integrated circuit 101 includes a top metal layer 114. The top metal layer 114 corresponds to the final metal layer. In the example of FIG. 3A, the top metal layer 114 is metal five (M5). However, other numbers of metal layers can be utilized without departing from the scope of the present disclosure. The metal layers 116 and the top metal layer 114 may each include aluminum, titanium, tungsten, cobalt, molybdenum, ruthenium, or other suitable conductive materials.

FIG. 3A illustrates a first cluster 103a of contact pads 104a, a second cluster 103b of contact pads 104B, and a die-level ESD protection line 108 have been formed from the top metal layer 114. A passivation layer 114 has been formed covering the contact pads 104 and the die-level ESD protection line 108.

Each contact pad 104a is coupled to the core circuitry 102 by a conductive path 118a. Each contact pad 104b is coupled to the core circuitry by a conductive path 118b. For simplicity, the conductive paths 118 are each shown as vertical conductive paths. However, in practice, each conductive path 118 may include a combination of metal tracks and conductive vias formed in conjunction with each of the metal layers 116.

FIG. 3A also illustrates that each of the conductive paths 118a is also coupled to ESD protection circuitry 106a. Each of the conductive paths 118b is coupled to ESD protection circuitry 106b. The ESD protection circuitry 106 is shown as cross coupled diodes. In practice, there may be a pair of cross coupled diodes connecting each respective conductive path 118 to the die-level ESD protection line 118. The ESD protection circuitry 106 can include protection circuits 121. The protection circuits 121 can include ESD protection transistors and other types of ESD protection circuitry without departing from the scope of the present disclosure.

Under standard operating conditions in which very low voltages are present within the integrated circuit 101, the ESD protection circuitry 106 ensures that the conductive paths 118 are not shorted to the die-level ESD protection line 118. However, when large voltages appear between contact pads 104 during an ESD event or other overvoltage event, the ESD protection circuitry 106 provides a conductive path from each of the conductive paths 118 to the die-level ESD protection line 108. The relatively low resistance of the conductive path provided by the ESD protection circuitry 106 helps ensure that high currents will not flow through the transistors of the core circuitry 102 but will instead flow to the ESD protection line 108 that is coupled to ground. More particularly, the ESD protection line 108 may be coupled to a buried ground structure or other type of ESD circuit.

In one embodiment, some portions of the ESD protection line 108 may be formed in other metal layers 116 in conjunction with conductive vias. Accordingly, the ESD protection line 108 may be formed entirely or partially within the top metal layer 114.

In FIG. 3A, a passivation layer 122 has been formed over the contact pads 104 and the die-level ESD protection line 108. The passivation layer 122 can correspond to one or more layers of dielectric material. Formation of the passivation layer 122 may correspond to completion of the wafer processing stage.

In FIG. 3B, the passivation layer 122 has been patterned to expose the contact pads 104. The passivation layer 122 has also been patterned to form openings 113 exposing the die-level ESD protection line 108. The patterning of the passivation layer 122 may either be part of the wafer processing stage or part of the packaging stage.

In FIG. 3C, a redistribution metal layer 124 has been formed and patterned, in accordance with one embodiment. During the wafer processing stage, the redistribution metal layer 124 is formed on the passivation layer 122 and on exposed portions of the top metal layer 114. In particular, the redistribution metal layer 124 is formed in contact with the contact pads 104 and in contact with the die-level ESD protection line 108 at the openings 113 and the passivation layer 122.

After patterning of the redistribution metal layer 124, the package level ESD protection line 110 is formed. The package level ESD protection line 110 shorts out a portion of the die-level ESD protection line 108. As described previously, the package level ESD protection line 110 has a lower resistance than the die-level ESD protection line 108. The result is that the overall resistance of the ESD protection line is reduced to a level that satisfies package level ESD protection standards. In one embodiment, the die-level ESD protection line 108 is aluminum with a resistance of about 8 ohms and the package level ESD protection line 110 is copper with a resistance of less than 1 ohm. Other materials can be utilized for the bilevel ESD protection line 108 and the package level ESD protection line 110 without departing from the scope of the present disclosure.

Though not shown in FIG. 3C, additional passivation layers may be formed over the redistribution metal layer 124 and patterned. Solder balls, solder bumps, or other types of electrical connectors may then be formed in contact with electrical traces of the redistribution metal layer 124 connecting to the contact pads 104.

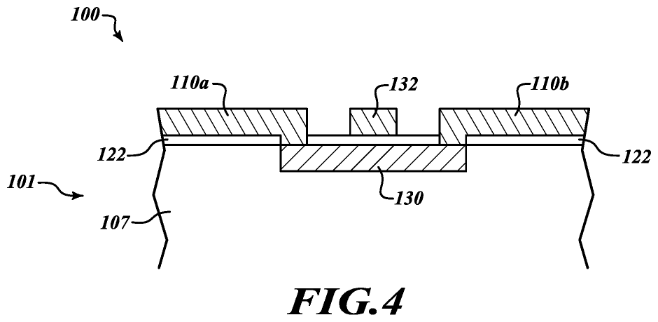

FIG. 4 is an enlarged cross-sectional view of a portion of an integrated circuit package 100, in accordance with one embodiment. While FIGS. 2 and 3C illustrates a package level ESD protection line 110 of a single continuous segment of the redistribution metal layer 124, in one embodiment the ESD protection line 110 can include multiple distinct segments coupled together by portions of the top metal layer 114.

In FIG. 4, a package level ESD protection line 110 includes a first package level ESD protection line 110a and a second package level ESD protection line 110b. A portion 132 of the redistribution metal layer 124 is positioned between the lines 110a and 110b. Accordingly, in some cases, due to the complex and dense structures formed of the redistribution metal layer, in order to avoid shorting other portions of the redistribution metal layer 124, the package level ESD protection line 110 is implemented as two distinct ESD protection lines 110a and 110b joined together by a short segment 130 of the top metal layer 114. As described previously, the passivation layer 122 may be patterned to provide openings so that the ESD protection lines 110a and 110b can be coupled to the segment 130 of the top metal layer 114. Various configurations of ESD protection lines 110 and segments 130 can be utilized without departing from the scope of the present disclosure.

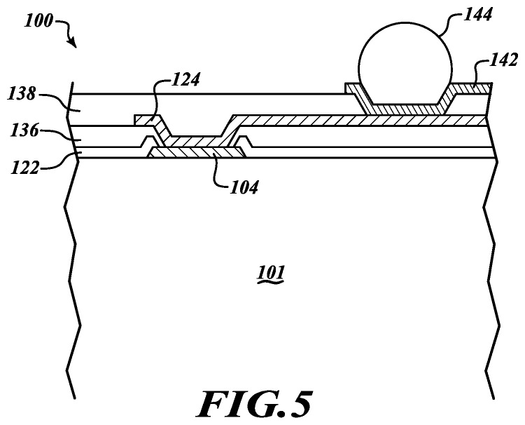

FIG. 5 is an enlarged cross-sectional view of a portion of an integrated circuit package 100, in accordance with one embodiment. FIG. 5 illustrates one example of how a packaging stage may be implemented to connect a contact pad 104 with a solder ball 144, in accordance with one embodiment. In particular, the passivation layer 122 is patterned to expose the contact pad 104. A second passivation layer 136 is then formed on the passivation layer 122. The passivation layer 136 may include one or more layers of dielectric material. The passivation layer 136 is patterned to expose the contact pad 104. Though not shown in FIG. 5, the passivation layer 136 and the passivation layer 122 may also be patterned to form openings 113 exposing portions of a die-level ESD protection line 108.

The redistribution layer 124 is then formed on the passivation layer 136 and on the contact pad 104. The redistribution layer 124 is patterned to form traces that each individually connect to a respective contact pads 104. A third passivation layer 138 including one or more layers of dielectric material is then formed on the redistribution metal layer 124. The passivation layer 138 is then patterned to expose a portion of the redistribution metal layer 124. The metal connector 142 is then formed in contact with the passivation layer 138. The solder ball 144 is then placed on the metal connector 142 and is electrically coupled to the contact pad 104 by the redistribution metal layer 124. Other packaging schemes can be utilized without departing from the scope of the present disclosure.

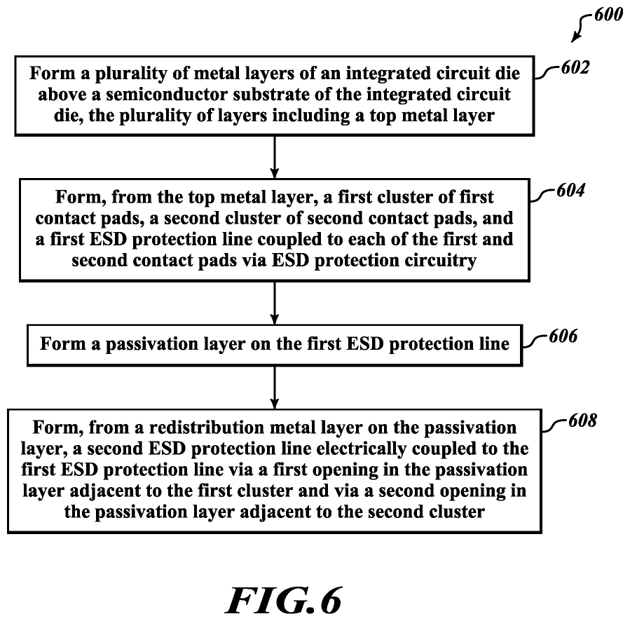

FIG. 6 is a flow diagram of a method 600 for forming an integrated circuit package, according to one embodiment. The method 600 can utilize components, processes, and structures shown in relation to FIGS. 1-5. At 602, the method 600 includes forming a plurality of metal layers of an integrated circuit die above a semiconductor substrate of the integrated circuit die, the plurality of layers including a top metal layer. At 604, the method 600 includes forming, from the top metal layer, a first cluster of first contact pads, a second cluster of second contact pads, and a first ESD protection line coupled to each of the first and second contact pads via ESD protection circuitry. At 606, the method 600 includes forming a passivation layer on the first ESD protection line. At 608, the method 600 includes forming, from a redistribution metal layer on the passivation layer, a second ESD protection line electrically coupled to the first ESD protection line via a first opening in the passivation layer adjacent to the first cluster and via a second opening in the passivation layer adjacent to the second cluster.

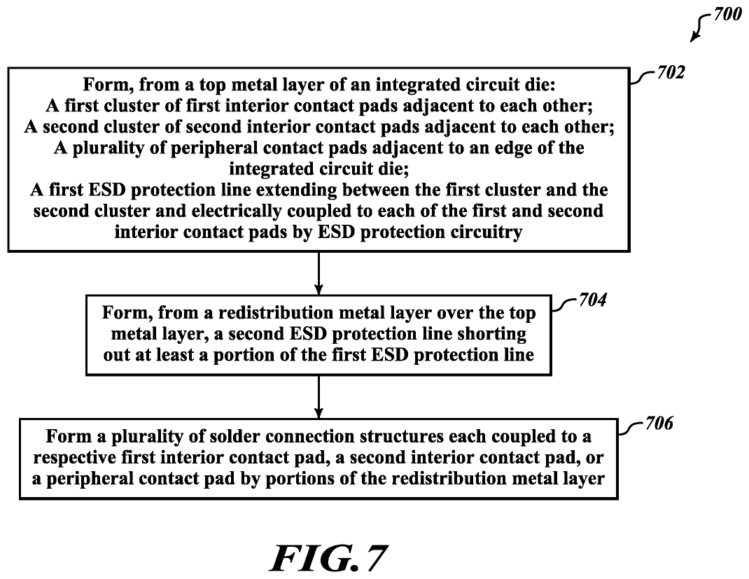

FIG. 7 is a flow diagram of a method 700 for forming an integrated circuit package, according to one embodiment. The method 700 can utilize components, processes, and structures shown in relation to FIGS. 1-6. At 702, the method 700 includes forming, from a top metal layer of an integrated circuit die, a first cluster of first interior contact pads adjacent to each other, a second cluster of second interior contact pads adjacent to each other, a plurality of peripheral contact pads adjacent to an edge of the integrated circuit die, and a first ESD protection line extending between the first cluster and the second cluster and electrically coupled to each of the first and second interior contact pads by ESD protection circuitry. At 704, the method 700 includes forming, from a redistribution metal layer over the top metal layer, a second ESD protection line shorting out at least a portion of the first ESD protection line. At 706, the method 700 include forming a plurality of solder connection structures each coupled to a respective first interior contact pad, a second interior contact pad, or a peripheral contact pad by portions of the redistribution metal layer.

In one embodiment, a device includes an integrated circuit die including core circuitry implemented in one or more layers of semiconductor material and a first cluster of first contact pads formed of a top metal layer of the integrated circuit die and coupled to the core circuitry. In one embodiment, the integrated circuit die includes a second cluster of second contact pads formed of the top metal layer and coupled to the core circuitry, a first ESD protection line formed of the top metal layer extending between an area of the first cluster and an area of the second cluster, and ESD protection circuitry in the one or more layers of semiconductor material coupling each of the first contact pads and each of the second contact pads to the first ESD protection line by ESD protection circuitry. The device includes a passivation layer on the integrated circuit die and a second ESD protection line on the passivation layer formed of a redistribution metal layer and shorting a portion of the first ESD protection line.

In one embodiment, a method includes forming a plurality of metal layers of an integrated circuit die above a semiconductor substrate of the integrated circuit die, the plurality of layers including a top metal layer and forming, from the top metal layer, a first cluster of first contact pads, a second cluster of second contact pads, and a first ESD protection line coupled to each of the first and second contact pads via ESD protection circuitry. The method includes forming a passivation layer on the first ESD protection line and forming, from a redistribution metal layer on the passivation layer, a second ESD protection line electrically coupled to the first ESD protection line via a first opening in the passivation layer adjacent to the first cluster and via a second opening in the passivation layer adjacent to the second cluster.

In one embodiment, a method includes a forming, from a top metal layer of an integrated circuit die a first cluster of first interior contact pads adjacent to each other, a second cluster of second interior contact pads adjacent to each other, a plurality of peripheral contact pads adjacent to an edge of the integrated circuit die, and a first ESD protection line extending between the first cluster and the second cluster and electrically coupled to each of the first and second interior contact pads by ESD protection circuitry. The method includes forming, from a redistribution metal layer over the top metal layer, a second ESD protection line shorting out at least a portion of the first ESD protection line and forming a plurality of solder connection structures each coupled to a respective first interior contact pad, a second interior contact pad, or a peripheral contact pad by portions of the redistribution metal layer.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
an integrated circuit die including:
core circuitry implemented in one or more layers of semiconductor material;
a first cluster of first contact pads formed of a top metal layer of the integrated circuit die and coupled to the core circuitry;
a second cluster of second contact pads formed of the top metal layer and coupled to the core circuitry;
a first ESD protection line formed of the top metal layer extending between an area of the first cluster and an area of the second cluster; and
ESD protection circuitry in the one or more layers of semiconductor material coupling each of the first contact pads and each of the second contact pads to the first ESD protection line by ESD protection circuitry;
a passivation layer on the integrated circuit die; and
a second ESD protection line on the passivation layer formed of a redistribution metal layer and shorting a portion of the first ESD protection line.

2. The device of claim 1, comprising solder balls electrically balls each electrically coupled to one of the first contact pads or the second contact pads.

3. The device of claim 1, comprising a third ESD protection line formed of the redistribution metal layer, wherein the integrated circuit die includes:
a third cluster of third contact pads formed of the top metal layer; and
an ESD connection line formed of the top metal layer and electrically coupling the third ESD protection line to the second ESD protection line, wherein the third ESD protection line is coupled to each of the third contact pads by the ESD protection circuitry.

4. The device of claim 1, wherein the ESD protection circuitry includes diodes.

5. The device of claim 1, wherein the first ESD protection line is coupled to ground.

6. The device of claim 1, wherein the second ESD protection line is coupled to the first ESD protection line at a first location by a first opening in the passivation layer and at a second location via a second opening in the passivation layer.

7. The device of claim 1, wherein the second ESD protection line has lower resistance between the first cluster and the second cluster than does the first ESD protection line.

8. The device of claim 1, wherein the top metal layer includes aluminum and the redistribution metal layer includes copper.

9. The device of claim 1, wherein the integrated circuit includes:
a plurality of third contact pads formed of the top metal layer and positioned adjacent to an edge of the integrated circuit die; and
a ground ring below the third contact pads.

10. The device of claim 9, wherein the first and second clusters are further from the edge than are the contact pads.

11. The device of claim 1, wherein the core circuitry includes transistors.

12. A method, comprising:
forming a plurality of metal layers of an integrated circuit die above a semiconductor substrate of the integrated circuit die, the plurality of layers including a top metal layer;
forming, from the top metal layer, a first cluster of first contact pads, a second cluster of second contact pads, and a first ESD protection line coupled to each of the first and second contact pads via ESD protection circuitry;
forming a passivation layer on the first ESD protection line; and
forming, from a redistribution metal layer on the passivation layer, a second ESD protection line electrically coupled to the first ESD protection line via a first opening in the passivation layer adjacent to the first cluster and via a second opening in the passivation layer adjacent to the second cluster.

13. The method of claim 12, comprising forming the top metal layer during a wafer processing stage.

14. The method of claim 13, comprising forming the redistribution metal layer during a packaging stage.

15. The method of claim 12, comprising:
forming, from the top metal layer, an ESD connection line; and
forming, from the redistribution metal layer, a third ESD protection line electrically coupled to the second ESD protection line by the ESD connection line.

16. The method of claim 12, wherein the first ESD protection line has a higher resistance between the first and second clusters than does the second ESD protection line.

17. The method of claim 16, wherein the first top metal layer includes aluminum and the redistribution metal layer includes copper.

18. A method, comprising:
forming, from a top metal layer of an integrated circuit die:
a first cluster of first interior contact pads adjacent to each other;
a second cluster of second interior contact pads adjacent to each other;
a plurality of peripheral contact pads adjacent to an edge of the integrated circuit die;
a first ESD protection line extending between the first cluster and the second cluster and electrically coupled to each of the first and second interior contact pads by ESD protection circuitry;
forming, from a redistribution metal layer over the top metal layer, a second ESD protection line shorting out at least a portion of the first ESD protection line; and
forming a plurality of solder connection structures each coupled to a respective first interior contact pad, a second interior contact pad, or a peripheral contact pad by portions of the redistribution metal layer.

19. The method of claim 18, wherein the first ESD protection line has a higher resistance between the first and second clusters than does the second ESD protection line.

20. The method of claim 19, wherein the first top metal layer includes aluminum and the redistribution metal layer includes copper.
